(19) United States
(12) Patent Application Publication
(10) Pub. No.: US 2016/0141037 A1
(43) Pub. Date: May 19, 2016

(54) SEMICONDUCTOR MEMORY SYSTEM AND METHOD OF OPERATING THE SAME

(71) Applicant: SK hynix Inc., Gyeonggi-do (KR)

(72) Inventor: Sang-Sik KIM, Gyeonggi-do (KR)

(21) Appl. No.: 14/673,457

(22) Filed: Mar. 30, 2015

(30) Foreign Application Priority Data
Nov. 13, 2014 (KR) 10-2014-0158115

(51) Int. Cl. G11C 16/10; G11C 29/52; G06F 11/10

(52) U.S. Cl. CPC G11C 16/107; G06F 11/1068; G11C 29/52

(57) ABSTRACT

A method of operating a semiconductor memory system includes: programming LSB data into a memory cell of a selected word line included in a memory block; storing MSB data to be programmed into the memory cell of the selected word line, from a controller into a page buffer; reading the programmed LSB data from the memory cell of the selected word line; performing an ECC operation on the read LSB data when a difference between a reference amount and an amount of bit line current, which flows through bit lines included in the memory block, does not fall in a predetermined range from a first current amount to a second current amount; and programming the MSB data stored in the page buffer into the memory cell of the selected word line based on the ECC-corrected LSB data.

### CROSS-REFERENCE TO RELATED APPLICATIONS

The present application claims priority of Korean Patent Application No. 10-2014-0158115, filed on Nov. 13, 2014, which is incorporated herein by reference in its entirety.

### BACKGROUND

1. Field

Various exemplary embodiments of the present invention relate to a semiconductor memory system and, more particularly, to a method of programming a multi-level cell.

2. Description of the Related Art

A semiconductor device generally includes a memory controller and a memory device. A NAND flash memory device is a nonvolatile memory device capable of retaining data when power supply is interrupted. Recently, NAND flash memory devices have been created that are capable of storing 2-bit data, including a least significant bit (LSB) and a most significant bit (MSB), in a single multi-level cell (MLC), in order to improve data storage capacity.

Before the semiconductor device performs an MSB programming operation on the memory cell, in order to store the MSB data into the memory cell, the semiconductor device performs a LSB programming operation on the memory cell to store the LSB data into the memory cell. The MSB programming operation requires the LSB data, which corresponds to the MSB data to be programmed and is already stored in the memory cell. However, the memory device reads the LSB data corresponding to the MSB data to be programmed without control of the memory controller during the MSB programming operation since the memory controller does not provide the LSB data. The memory device programs the LSB data, which is read without control of the memory controller, and the MSB data, which is provided from the memory controller, into the memory cell.

As described above, since the LSB data is read without control of the memory controller during the MSB programming operation, an error correction code (ECC) operation is not performed on the LSB data. That is, during the MSB programming operation, the memory device reads the LSB data without the ECC operation on the LSB data, and programs the LSB data and the MSB data into the memory cell. Therefore, reliability of the LSB data may not be secured when the threshold voltage distribution of the memory cell is distorted due to data retention or read disturbance stress.

In order to secure the reliability of the LSB data, the memory controller may read the LSB data from the memory device, perform an ECC operation on the LSB data, and provide the LSB data and the MSB data to the memory device, during the MSB programming operation. In such case, however, it takes a lot of time to program the MSB data since the memory controller reads the LSB data and performs the ECC operation on the LSB data whenever the MSB data is programmed during the MSB programming operation.

As an alternative, the memory controller may store the LSB data into its buffer whenever the LSB data is programmed. Then, during the MSB programming operation, the memory controller may provide the corresponding LSB data, stored in the buffer, and reduce the time required for an MSB programming operation. However, to perform this alternative method, there needs to be a buffer in the memory controller to store the LSB data.

### SUMMARY

Various embodiments of the present invention are directed to a method of operating a semiconductor memory system capable of reliably reading LSB data corresponding to MSB data during a MSB programming operation on a multi-level cell.

In accordance with an embodiment of the present invention, a method of operating a semiconductor memory system may include: programming LSB data into a memory cell of a selected word line included in a memory block; storing MSB data to be programmed into the memory cell of the selected word line, from a controller into a page buffer; reading the programmed LSB data from the memory cell of the selected word line; performing an ECC operation on the read LSB data when a difference between a reference amount and an amount of bit line current, which flows through bit lines included in the memory block, does not fall in a predetermined range from a first current amount to a second current amount; and programming the MSB data stored in the page buffer into the memory cell of the selected word line based on the ECC-corrected LSB data.

In accordance with an embodiment of the present invention, a method of operating a semiconductor memory system may include: programming LSB data into a memory cell of a selected word line included in a memory block; storing MSB data to be programmed into the memory cell of the selected word line, from a controller into a page buffer; reading the programmed LSB data from the memory cell of the selected word line in response to a read voltage when a difference between a reference amount and an amount of bit line current, which flows through bit lines included in the memory block, does not fall in a predetermined range from a first current amount to a second current amount; reading the programmed LSB data from the memory cell of the selected word line by changing the read voltage until the difference falls in the predetermined range; and programming the MSB data stored in the page buffer into the memory cell of the selected word line based on the read LSB data when the difference falls in the predetermined range.

In accordance with an embodiment of the present invention, a semiconductor memory system may include: a page buffer including LSB data and MSB data; a memory block including a memory cell suitable for storing the LSB data and the MSB data provided from the page buffer; and a current management unit suitable for determining whether a difference between a reference amount and an amount of bit line current, which flows through bit lines included in the memory block when the LSB data programmed in the memory cell are read for the MSB data to be programmed into the memory cell, falls in a predetermined range from a first current amount to a second current amount. The semiconductor memory system may perform an ECC operation on the LSB data when the difference between the reference amount and the amount of bit line current does not fall in the predetermined range, and the page buffer may program the MSB data based on the ECC-corrected LSB data.

In accordance with an embodiment of the present invention, a semiconductor memory system may include: a memory block including a memory cell in which LSB data are programmed; a voltage supply unit suitable for supplying a read voltage for reading the LSB data programmed in the memory cell; a page buffer suitable for receiving MSB data from a controller, and reading the LSB data programmed in the memory cell; and a current management unit suitable for determining whether a difference between a reference amount and an amount of bit line current, which flows through bit lines included in the memory block when the LSB data programmed in the memory cell are read for the MSB data to be programmed into the memory cell, falls in a predetermined range from a first current amount to a second current amount. When the difference between the reference amount and the amount of bit line current does not fall in the predetermined range, the voltage supply unit may change the read voltage until the difference falls in the predetermined range, and the page buffer reads the LSB data programmed in the memory cell in response to the changed read voltage.

In accordance with various embodiments of the present invention, when LSB data corresponding to MSB data are read during an MSB programming operation, an error in the LSB data may be detected on the basis of a total amount of current flowing through all bit lines of a memory block. Therefore, reliable LSB data may be read without performance deterioration of the MSB programming operation or without an additional buffer in a memory controller.

### BRIEF DESCRIPTION OF THE DRAWINGS

FIG. 1 is a block diagram illustrating a semiconductor memory system in accordance with an embodiment of the present invention.

FIG. 2 is a circuit diagram illustrating a memory block shown in FIG. 1.

FIG. 3 is a flow chart illustrating an operation of a semiconductor memory system in accordance with an embodiment of the present invention.

FIGS. 4A, 4B and 4C are schematic diagrams illustrating a relationship between a reference current and a detected amount of bit line current.

FIG. 5 is a flow chart illustrating an operation of a semiconductor memory system in accordance with an embodiment of the present invention.

FIGS. 6 to 10 are diagrams schematically illustrating a three-dimensional (3D) nonvolatile memory device in accordance with an embodiment of the present invention.

FIGS. 11 to 13 are diagrams schematically illustrating a 3D nonvolatile memory device in accordance with an embodiment of the present invention.

FIG. 14 is a block diagram schematically illustrating an electronic device including a semiconductor memory system in accordance with an embodiment of the present invention.

FIG. 15 is a block diagram schematically illustrating an electronic device including a semiconductor memory system in accordance with an embodiment of the present invention.

FIG. 16 is a block diagram schematically illustrating an electronic device including a semiconductor memory system in accordance with an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art. The drawings are not necessarily to scale and, in some instances, proportions may have been exaggerated to clearly illustrate features of the embodiments. Throughout the disclosure, reference numerals correspond directly to the like parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween. When a first layer is referred to as being “on” a second layer or “on” a substrate, it not only refers to where the first layer is formed directly on the second layer or the substrate, but also to where a third layer exists between the first layer and the second layer or the substrate.

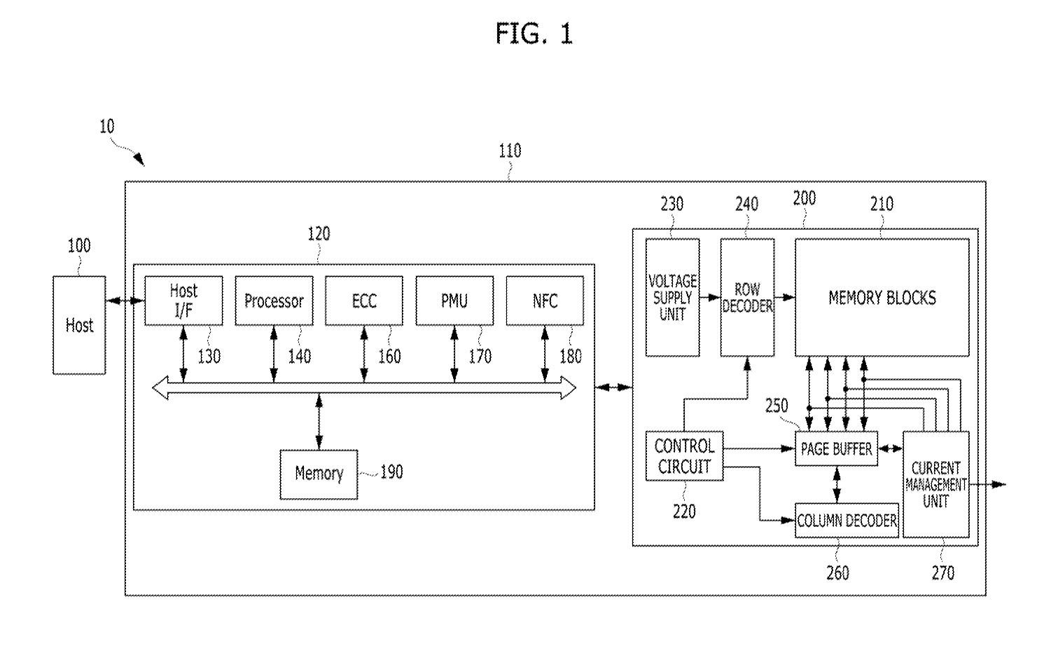

FIG. 1 is a block diagram illustrating a semiconductor memory system in accordance with an embodiment of the present invention. FIG. 1 exemplarily shows a data processing system 10, including a semiconductor memory system 110, in accordance with an embodiment of the present invention.

Referring to FIG. 1, the data processing system 10 may include a host 100 and the semiconductor memory system 110.

The host 100 may include a portable electronic devices, such as a cellular phone, an MP3 player, a laptop computer, and so forth, and electronic devices such as a desktop computer, a game player, a TV, a projector, and so forth.

The semiconductor memory system 110 may operate in response to a request from the host 100, and may store data to be accessed by the host 100. That is, the semiconductor memory system 110 may serve as a main storage device or a secondary storage device of the host 100. The semiconductor memory system 110 may be implemented with one of various storage devices according to a host interface protocol coupled to the host 100. For example, the semiconductor memory system 110 may be implemented with a storage device such as a solid state drive (SSD), a multimedia card (MMC), an embedded MMC (eMMC), a reduced-size multimedia card (RS-MMC), a micro-size version of MMC (MMCmicro), a secure digital (SD) card, a mini secure digital (miniSD) card, a micro secure digital (microSD) card, a secure digital high capacity (SDHC), a universal storage bus (USB) storage device, a universal flash storage (UFS) device, a compact flash (CF) card, a smart media (SM) card, a memory stick, and so forth.

The storage devices may be implemented with one or more of volatile memory devices such as a Dynamic Random Access Memory (DRAM) and a Static RAM (SRAM), and nonvolatile memory devices such as a Read Only Memory (ROM), a Mask ROM (MROM), a Programmable ROM (PROM), an Erasable PROM (EPROM), an Electrically Erasable PROM (EEPROM), a Ferromagnetic RAM (FRAM), a Phase change RAM (PRAM), a Magnetic RAM (MRAM), a Resistive RAM (RRAM) and a flash memory.

The semiconductor memory system 110 may include a semiconductor memory device 200 and a memory controller 120. The semiconductor memory device 200 may store data to be accessed by the host 100. The memory controller 120 may control storing data into the semiconductor memory device 200.

The memory controller 120 and the semiconductor memory device 200 may be integrated in a single semiconductor device. For example, the memory controller 120 and the semiconductor memory device 200 may be integrated in a single semiconductor device to configure the SSD. When the semiconductor memory system 110 is used in an SSD, the operation speed of the host 100 coupled to the semiconductor memory system 110 may be remarkably improved.

The memory controller 120 and the semiconductor memory device 200 may be integrated in a single semiconductor device such as a memory card. For example, the memory controller 120 and the semiconductor memory device 200 may be integrated in a single semiconductor device to configure a memory card such as a PC card of personal computer memory card international association (PCMCIA), a compact flash (CF) card, a smart media (SM) card, a memory stick, a multimedia card (MMC), a reduced-size multimedia card (RS-MMC), and a micro-size version of MMC (MMCmicro), a secure digital (SD) card, a mini secure digital (miniSD) card, a micro secure digital (microSD) card, a secure digital high capacity (SDHC), a universal flash storage (UFS), and so forth.

For another example, the semiconductor memory system 110 may be provided as one of various elements comprising an electronic device such as a computer, an ultra-mobile PC (UMPC), a workstation, a net-book computer, a personal digital assistants (PDA), a portable computer, a web tablet PC, a tablet computer, a wireless phone, a mobile phone, a smart phone, an e-book reader, a portable multimedia player (PMP), a portable game device, a navigation device, a black box, a digital camera, a digital multimedia broadcasting (DMB) player, a three-dimensional (3D) television, a smart television, a digital audio recorder, a digital audio player, a digital picture recorder, a digital picture player, a digital video recorder, a digital video player, a storage device of a data center, a device capable of receiving and transmitting information in a wireless environment, one of electronic devices of a home network, one of electronic devices of a computer network, one of electronic devices of a telematics network, a radio-frequency identification (RFID) device, or elements of a computing system.

The semiconductor memory device 200 of the semiconductor memory system 110 may retain data stored therein even when power supply is interrupted. The semiconductor memory device 200 may store data provided from the host 100 during a write operation, and may provide stored data to the host 100 during a read operation.

The semiconductor memory device 200 may include a memory block 210, a control circuit 220, a voltage supply unit 230, a row decoder 240, a page buffer 250, a column decoder 260, and a current management unit 270. The semiconductor memory device 200 may be a nonvolatile memory device, for example, a flash memory device. The semiconductor memory device 200 may have a three-dimensional (3D) stacked structure.

The memory block 210 may include a plurality of pages, each of which includes a plurality of memory cells coupled to a plurality of word lines WL.

The control circuit 220 may control overall operations of the semiconductor memory device 200 including program, erase and read operations.

The voltage supply unit 230 may supply word line voltages, for example, program, read, and pass voltages, to each of the plurality of word lines according to operation modes and may provide a voltage to a bulk, for example, a well region, where the plurality of memory cells are formed. The voltage supply unit 230 may supply the voltages under the control of the control circuit 220. The voltage supply unit 230 may supply a plurality of variable read voltages to generate a plurality of read data.

The row decoder 240 may select one of a plurality of memory blocks or sectors of the memory block 210, and may select one of the plurality of word lines of the selected memory block under the control of the control circuit 220. The row decoder 240 may provide the word line voltages, which are generated by the voltage supply unit 230, to the selected word line and the non-selected word lines, respectively, under the control of the control circuit 220.

The page buffer 250 may operate under the control of the control circuit 220. During the program operation, the page buffer 250 may serve as a write driver for driving bit lines based on data to be stored in a memory cell array of the memory block 210. During the program operation, the plurality of page buffers 250 may receive data to be programmed into the memory cell array from a buffer (not illustrated), and may drive the bit lines based on the received data. The plurality of page buffers 250 may correspond to a plurality of columns or bit lines, or to a plurality of column pairs or bit line pairs, respectively. The page buffer 250 may include a plurality of latches.

The current management unit 270 may detect an amount of bit line current I_{BL} flowing through the bit lines of the memory cell array when a programmed LSB data stored in the memory cell array is read out to the page buffer 250. The current management unit 270 may obtain a difference R_{PB} between a reference amount of reference current I_{ref} and the detected amount of the bit line current I_{BL}, may determine whether the difference R_{PB} between the reference current I_{ref} and the detected amount of the bit line current I_{BL} falls in a range from a first current amount R_{ref1} to a second current amount R_{ref2}, and may transmit error information including an error report and invalid LSB data to the memory controller 120 when the difference R_{PB} does not fall in the range from the first current amount R_{ref1} to the second current amount R_{ref2}.

The memory controller 120 of the semiconductor memory system 110 may control the semiconductor memory device 200 in response to the request from the host 100. For example, the memory controller 120 may provide to the host 100 data read from the semiconductor memory device 200, and may store into the semiconductor memory device 200 data provided from the host 100. To this end, the memory controller 120 may control the program, read, and erase operations of the semiconductor memory device 200.

The memory controller 120 may include a host interface unit 130, a processor 140, an ECC unit 160, a power management unit (PMU) 170, a NAND flash controller (NFC) 180, and a memory 190.

The hose interface unit 130 may process a command and data provided from the host 100. The host interface unit 130 may communicate with the host 100 through one or more of various interface protocols such as a universal serial bus (USB), a multi-media card (MMC), a peripheral component interconnect express (PCI-E), a small computer system interface (SCSI), a serial-attached SCSI (SAS), a serial advanced technology attachment (SATA), a parallel advanced technology attachment (PATA), an enhanced small disk interface (ESDI), and an integrated drive electronics (IDE).

The ECC unit 160 may detect and correct an error included in data read from the semiconductor memory device 200 during the read operation. The ECC unit 160 may perform an error correction code (ECC) decoding operation on data read from the semiconductor memory device 200, determine whether the ECC decoding operation succeeds, provide an instruction signal according to the determination result, and correct an error bit included in the read data based on parity bits generated through an ECC encoding operation. The ECC unit 160 may not correct error bits, the number of which exceeds the error correction capacity thereof, and may provide an ECC fail signal according to a failure of the ECC decoding operation.

The ECC unit 160 may correct an error based on a coded modulation such as a low-density parity-check (LDPC) code, a Bose-Chaudhuri-Hocquenghem (BCH) code, a turbo code, an Reed-Solomon (RS) code, a convolution code, a Recursive Systematic Code (RSC), a Trellis-Coded Modulation (TCM), a Block Coded Modulation (BCM), and so on. The ECC unit 160 may include all circuits, systems, or devices for error correction.

The NFC 180 may serve as an interface between the memory controller 120 and the semiconductor memory device 200 for the memory controller 120 to control the semiconductor memory device 200 in response to the request from the host 100. The NFC 180 may generate a control signal of the semiconductor memory device 200 and process data under the control of the processor 140 when the semiconductor memory device 200 is a flash memory device, for example, a NAND flash memory device.

The memory 190 may serve as an operation memory of the semiconductor memory system 110 and the memory controller 120, and may store data used for driving the semiconductor memory system 110 and the memory controller 120. When the memory controller 120 controls the semiconductor memory device 200 in response to the request of the host 100, for example, when the memory controller 120 provides to the host 100 data read from the semiconductor memory device 200, and stores into the semiconductor memory device 200 data provided from the host 100, the memory controller 120 controls the program, read, and erase operations of the semiconductor memory device 200. At this time, the memory 190 may store data required for such operations between the memory controller 120 and the semiconductor memory device 200.

The memory 190 may be implemented with volatile memory, for example, SRAM or DRAM. The memory 190 may store data required for operations between the memory controller 120 and the semiconductor memory device 200, data required for program and read operations, and data to be programmed and read during the program and read operations. To this end, the memory 190 may include program memory, data memory, write buffer, read buffer, map buffer, and so forth.

The processor 140 may perform a general control operation of the semiconductor memory system 110, and may control the program and read operations of the semiconductor memory device 200 in response to program and read requests from the host 100. The processor 140 may drive firmware, referred to as a flash translation layer (FTL), to perform general control operations of the semiconductor memory system 110. The processor 140 may be implemented with a microprocessor or a central processing unit (CPU).

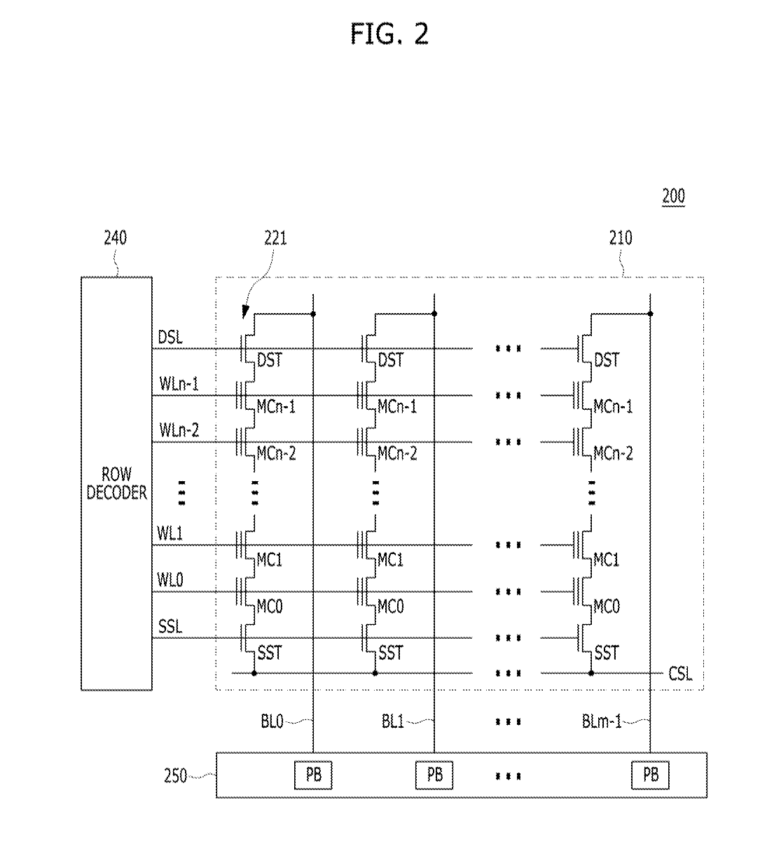

FIG. 2 is a circuit diagram illustrating the memory block 210 included in the semiconductor memory device 200 shown in FIG. 1.

Referring back to FIG. 2, the memory block 210 may include a plurality of cell strings 221 coupled to bit lines BL0 to BLm−1, respectively. The cell string 221 of each column may include one or more drain selection transistors DST and one or more source selection transistors SST. A plurality of memory cells or memory cell transistors may be serially coupled between the selection transistors DST and SST.

Each of the memory cells MC0 to MCn−1 may be formed multi-level cells (MLC), storing data information of multiple bits in each cell. The cell strings 221 may be electrically coupled to the corresponding bit lines BL0 to BLm−1, respectively.

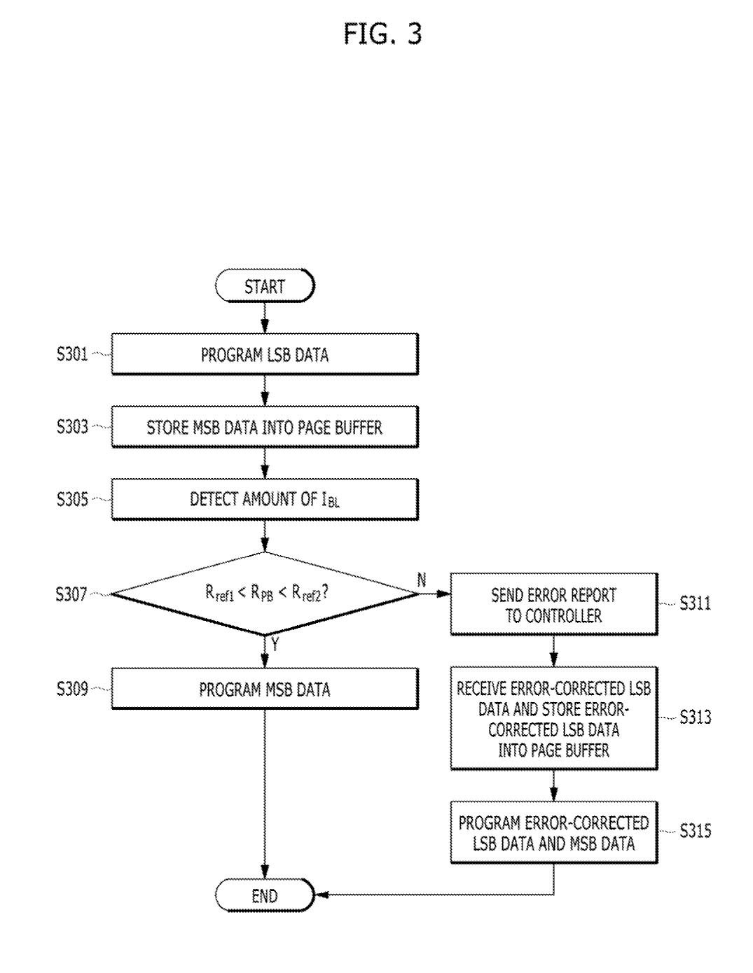

FIG. 3 is a flow chart illustrating an operation of the semiconductor memory system 110 in accordance with an embodiment of the present invention.

Hereinafter, referring to FIGS. 1 to 3, the operation of the semiconductor memory system 110 is described in detail.

Referring to FIG. 3, at step S301, the semiconductor memory device 200 may program LSB data into a memory cell of a selected word line included in the memory block 210.

At step S303, the semiconductor memory device 200 may receive MSB data, which is to be programmed in the memory cell of the selected word line, from the memory controller 120, and may store the received MSB data in the page buffer 250. The MSB data may be inputted to the page buffer 250 through an input/output unit (not shown) and the column decoder 260.

At step S305, the semiconductor memory device 200 may perform an LSB data read operation in order to read out the LSB data stored in the memory cell of the selected word line. To this end, the voltage supply unit 230 may supply a read voltage Vread to the selected word line and a pass voltage Vpass to the other word lines. The current management unit 270 may detect the amount of the bit line current I_{BL} flowing through the bit lines during the LSB data read operation on the memory cell of the selected word line.

At step S307, the current management unit 270 may obtain a difference R_{PB} between the reference current I_{ref} and the detected amount of the bit line current I_{BL} of step S305, and may determine whether the difference R_{PB} between the reference current I_{ref} and the detected amount of the bit line current I_{BL} falls in the range from the first current amount R_{ref1} to the second current amount R_{ref2} of the page buffer 250.

For example, the page buffer 250 may determine the first current amount R_{ref1} by detecting a total amount of current flowing through turned-on bit lines and turned-off bit lines when the number of turned-off memory cells in the selected word line becomes approximately 49% of the total number of the memory cells in a single word line. The page buffer 250 may determine the second current amount R_{ref2} by detecting a total amount of current flowing through turned-on bit lines and turned-off bit lines when the number of turned-off memory cells in the selected word line becomes approximately 51% of the total number of memory cells in a single word line.

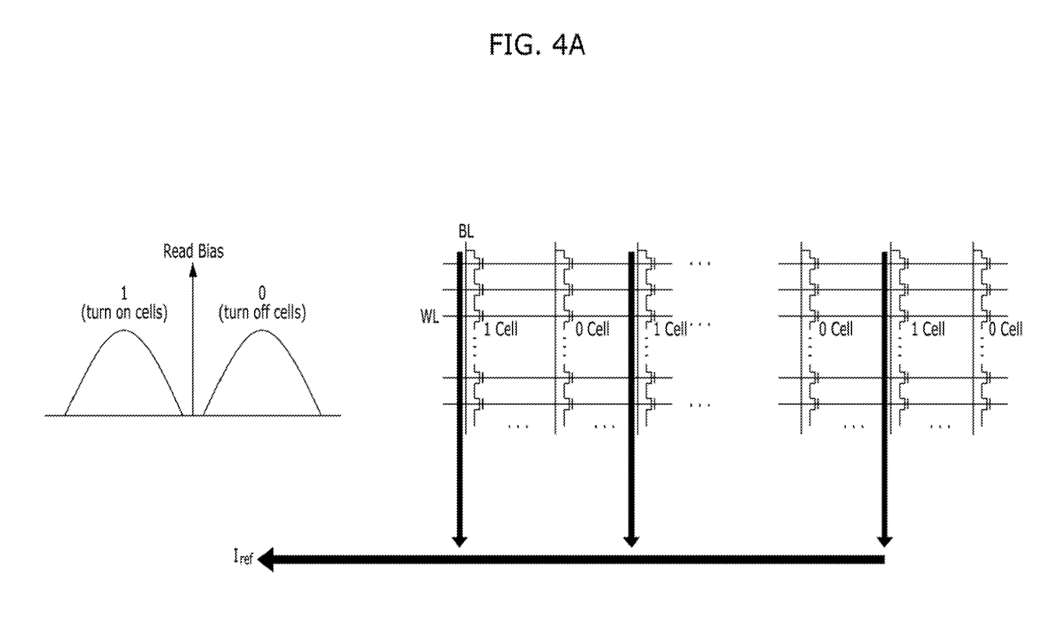

FIGS. 4A, 4B and 4C are schematic diagrams illustrating a relationship between the reference current I_{ref} and the detected amount of the bit line current I_{BL}.

The reference current I_{ref} may be a total amount of current flowing through turned-on bit lines and turned-off bit lines, and the detected amount of the bit line current I_{BL} may be an amount of current flowing through bit lines during the LSB data read operation on the memory cell of the selected word line.

Referring to FIG. 4A, an optimal read bias voltage, which corresponds to a read voltage with a minimum bit error rate, is located around the middle of the threshold voltage distribution of memory cells representing ‘0’ and the threshold voltage distribution of memory cells representing ‘1’. Ideally, the proportion of the memory cells representing ‘0’ and the memory cells representing ‘1’ is approximately 1:1. For example, when the LSB data of 16 KB is to be programmed, ideally, the turned-off memory cells of 8 KB may represent ‘0’, and the turned-on memory cell of the other 8 KB may represent ‘1’. That is, the reference current I_{ref} may be the total amount of current flowing through the turned-on bit lines and the turned-off bit lines in the ideal case.

Referring to FIG. 4B, the number of turned-on bit lines increases as the threshold voltage distribution of the memory cells representing ‘0’ is distorted so that the threshold voltages of a part of the memory cells representing ‘0’ becomes lower than the optimal read bias voltage due to data retention or read disturbance stress. As the number of turned-on bit lines increases, the total amount of current flowing through the bit lines increases and therefore the detected amount of bit line current I_{BL} may be greater than the reference current I_{ref}.

Referring to FIG. 4C, the number of turned-off bit lines increases as the threshold voltage distribution of the memory cells representing ‘1’ is distorted so that the threshold voltages of a part of the memory cells representing ‘1’ increase over the optimal read bias voltage due to the data retention or the read disturb stress. As the number of turned-off bit lines becomes greater, the total amount of current flowing through the bit lines decreases and therefore the detected amount of bit line current I_{BL} may be smaller than the reference current I_{ref}.

For example, the page buffer 250 may determine the first current amount R_{ref1} by detecting a total amount of current flowing through turned-on bit lines and turned-off bit lines when the number of turned-off memory cells in the selected word line becomes approximately 49% of the total number of the memory cells in a single word line. The page buffer 250 may determine the second current amount R_{ref2} by detecting a total amount of current flowing through turned-on bit lines and turned-off bit lines when the number of turned-off memory cells in the selected word line becomes approximately 51% of the total number of memory cells in a single word line.

As such, the current management unit 270 at step S307 may determine whether the read LSB data includes an error by determining the difference R_{PB} between the reference current I_{ref} and the detected amount of the bit line current I_{BL}, which is detected at step S305, falls in the predetermined range from the first current amount R_{ref1} to the second current amount R_{ref2}.

When it is determined at step S307 that the difference R_{PB} between the reference current I_{ref} and the detected amount of the bit line current I_{BL} falls in the predetermined range from the first current amount R_{ref1} to the second current amount R_{ref2}, which may mean that the read LSB data does not include an error, the current management unit 270 may program the MSB data, which is temporarily stored in the page buffer 250 at step S303, into the memory cell of the selected word line at step S309.

When it is determined at step S307 that the difference R_{PB} between the reference current I_{ref} and the detected amount of the bit line current I_{BL} does not fall in the predetermined range from the first current amount R_{ref1} to the second current amount R_{ref2}, which may mean that the read LSB data includes an error, the current management unit 270 may transmit the error information including the error report and the invalid LSB data to the memory controller 120 at step S311.

At step S313, the memory controller 120 may perform an ECC operation on the invalid LSB data, which is transmitted from the current management unit 270, and may provide the ECC-corrected LSB data to the page buffer 250.

At step S315, the page buffer 250 may program the ECC-corrected LSB data, which is provided from the memory controller 120 at step S313, and the MSB data, which is temporarily stored in the page buffer 250 at step S303, into the memory cell of the selected word line.

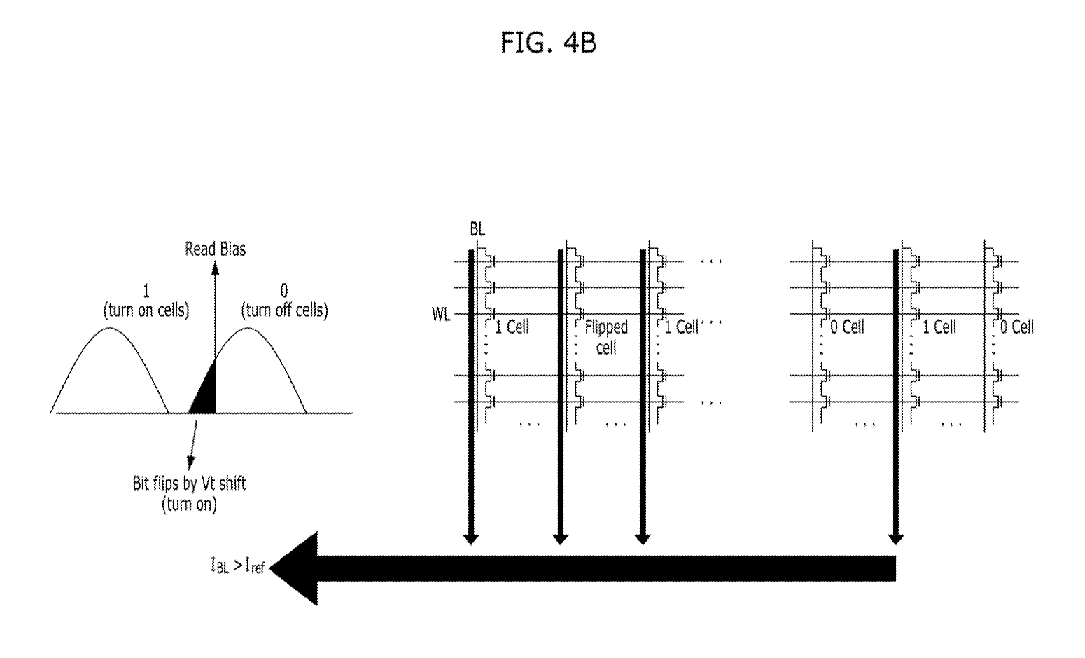

FIG. 5 is a flow chart illustrating an operation of the semiconductor memory system 110 in accordance with an embodiment of the present invention.

Hereinafter, referring to FIGS. 1 to 3, the operation of the semiconductor memory system 110 is described in detail.

Referring to FIG. 5, at step S501, the semiconductor memory device 200 may program LSB data into a memory cell of a selected word line included in the memory block 210.

At step S503, the semiconductor memory device 200 may receive MSB data, which is to be programmed into the memory cell of the selected word line, from the memory controller 120, and may store the received MSB data in the page buffer 250. The MSB data may be inputted to the page buffer 250 through an input/output unit (not shown) and the column decoder 260.

At step S505, the semiconductor memory device 200 may perform a LSB data read operation to read out the LSB data stored in the memory cell of the selected word line. To this end, the voltage supply unit 230 may supply a read voltage Vread to the selected word line and a pass voltage Vpass to the other word lines. The current management unit 270 may detect the amount of bit line current I_{BL} flowing through the bit lines during the LSB data read operation on the memory cell of the selected word line.

At step S507, the current management unit 270 may obtain a difference R_{PB} between the reference current I_{ref} and the detected amount of bit line current I_{BL} of step S505, and may determine whether the difference R_{PB} between the reference current I_{ref} and the detected amount of bit line current I_{BL} falls in the range from the first current amount R_{ref1} to the second current amount R_{ref2}.

The reference current I_{ref} may be the total amount of current flowing through turned-on bit lines and turned-off bit lines, and the detected amount of bit line current I_{BL} may be an amount of current flowing through bit lines during the LSB data read operation on a memory cell of the selected word line.

Referring to FIG. 4A, an optimal read bias voltage, which corresponds to a read voltage with a minimum bit error rate, is located around the middle of the threshold voltage distribution of memory cells representing ‘0’ and the threshold voltage distribution of memory cells representing ‘1’. Ideally, the proportion of the memory cells representing ‘0’ and the memory cells representing ‘1’ is approximately 1:1. For example, when the LSB data of 16 KB is to be programmed, ideally, the memory cells of 8 KB may represent ‘0’, and the memory cell of the other 8 KB may represent ‘1’. The reference current I_{ref} may be the total amount of current flowing through turned-on bit lines and turned-off bit lines in the ideal case.

Referring to FIG. 4B, the number of turned-on bit lines increases as the threshold voltage distribution of the memory cells representing ‘0’ is distorted so that the threshold voltages of a part of the memory cells representing ‘0’ becomes lower than the optimal read bias voltage due to data retention or read disturbance stress. As the number of turned-on bit lines increases, the total amount of current flowing through the bit lines increases and, therefore, the detected amount of bit line current I_{BL} may be greater than the reference current I_{ref}.

Referring to FIG. 4C, the number of turned-off bit lines increases as the threshold voltage distribution of the memory cells representing ‘1’ is distorted so that the threshold voltages of part of the memory cells representing ‘1’ becomes greater than the optimal read bias voltage due to data retention or read disturbance stress. As the number of the turned-off bit lines increases, the total amount of current flowing through the bit lines decreases and, therefore, the detected amount of bit line current I_{BL} may be smaller than the reference current I_{ref}.

For example, the page buffer 250 may determine the first current amount R_{ref1} by detecting a total amount of current flowing through turned-on bit lines and turned-off bit lines when the number of turned-off memory cells in the selected word line becomes approximately 49% of the total number of memory cells in a single word line. The page buffer 250 may determine the second current amount R_{ref2} by detecting a total amount of current flowing through turned-on bit lines and turned-off bit lines when the number of turned-off memory cells in the selected word line becomes approximately 51% of the total number of memory cells in a single word line.

As such, the current management unit 270 at step S507 may determine whether the read LSB data includes an error by determining the difference R_{PB} between the reference current I_{ref} and the detected amount of the bit line current I_{BL}, which is detected at step S505, falls in the predetermined range from the first current amount R_{ref1} to the second current amount R_{ref2}.

When it is determined at step S507 that the difference R_{PB} between the reference current I_{ref} and the detected amount of the bit line current I_{BL} falls in the predetermined range from the first current amount R_{ref1} to the second current amount R_{ref2}, which may mean that the read LSB data does not include any errors, the current management unit 270 may program the MSB data, which is temporarily stored in the page buffer 250 at step S503, into the memory cell of the selected word line at step S509.

When it is determined at step S507 that the difference R_{PB} between the reference current I_{ref} and the detected amount of the bit line current I_{BL} does not fall in the predetermined range from the first current amount R_{ref1} to the second current amount R_{ref2}, which may mean that the read LSB data includes an error, the voltage supply unit 230 may reset and supply the read voltage Vread to the selected word line at step S511. Steps S505, S507, and S511 may be repeated a predetermined number of times until the difference R_{PB} between the reference current I_{ref} and the detected amount of the bit line current I_{BL} falls in the predetermined range from the first current amount R_{ref1} of current to the second amount R_{ref2} of current of the page buffer 250.

When the semiconductor memory device 200 of the semiconductor memory system 110 in accordance with an embodiment of the present invention is implemented with a three-dimensional (3D) nonvolatile memory device, the semiconductor memory device will be described in more detail.

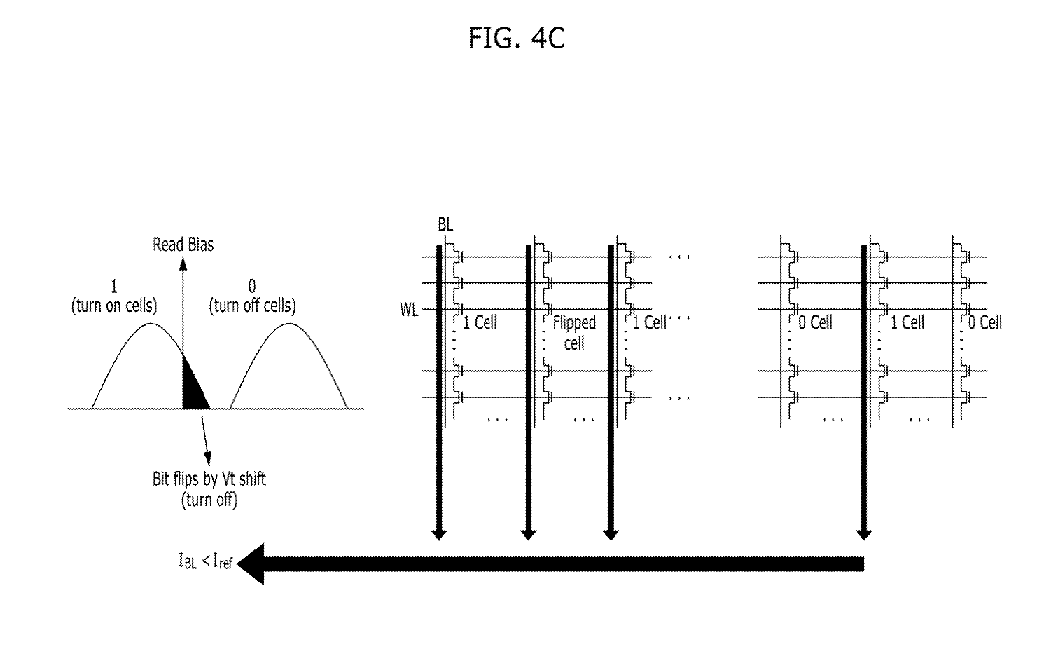

FIGS. 6 to 10 are diagrams schematically illustrating a three-dimensional (3D) nonvolatile memory device in accordance with an embodiment of the present invention. FIGS. 6 to 10 illustrate the semiconductor memory device, for example a flash memory device implemented in 3D in accordance with an embodiment of the present invention.

FIG. 6 is a block diagram illustrating the memory cell array of the memory block 210 shown in FIG. 1.

Referring to FIG. 6, the memory cell array may include a plurality of memory blocks BLK1 to BLKj. Each of the memory blocks BLK1 to BLKj may have a 3D structure or a vertical structure. For example, each of the memory blocks BLK1 to BLKj may include a structure extending along first to third directions.

Each of the memory blocks BLK1 to BLKj may include a plurality of NAND strings NS extending along the second direction. A plurality of NAND strings NS may be provided along the first and third directions. Each of the NAND strings NS may be coupled to a bit line BL, one or more string select lines SSL, one or more ground select lines GSL, a plurality of word lines WL, one or more dummy word lines DWL, and a common source line CSL. That is, each of the memory blocks BLK1 to BLKj may be coupled to a plurality of bit lines BL, a plurality of string select lines SSL, a plurality of ground select lines GSL, a plurality of word lines WL, a plurality of dummy word lines DWL, and a plurality of common source lines CSL.

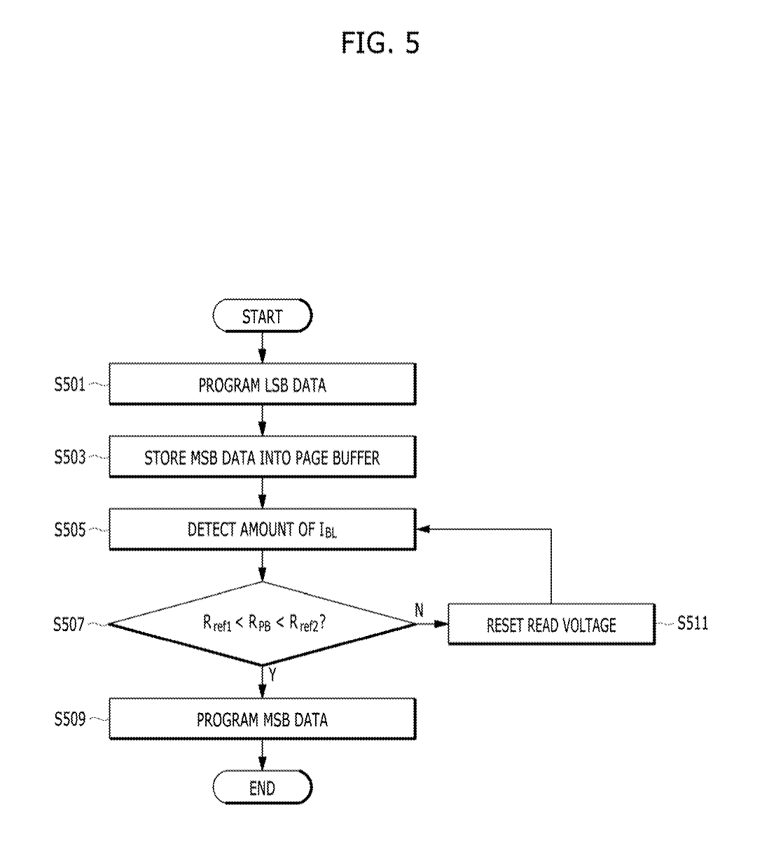

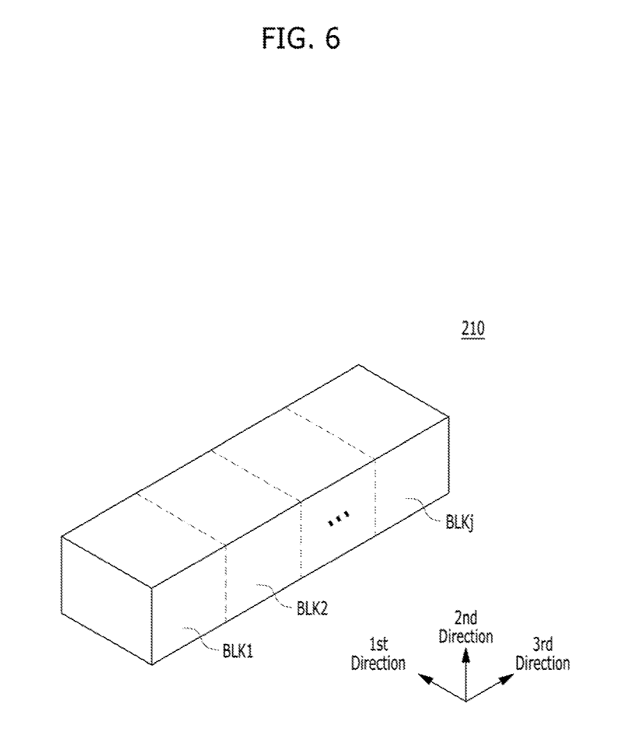

FIG. 7 is a perspective view of one memory block BLKj of the memory blocks BLK1 to BLKj shown in FIG. 6. FIG. 8 is a cross-sectional view taken along a line I-I′ of the memory block BLKj shown in FIG. 7.

Referring to FIGS. 7 and 8, the memory block BLKj may include a structure extending along first to third directions.

A substrate 1111 may be provided. For example, the substrate 1111 may include a silicon material doped by a first type impurity. For example, the substrate 1111 may include a silicon material doped by a p-type impurity or a p-type well, e.g., a pocket p-well. The substrate 1111 may further include an n-type well surrounding the p-type well. In the embodiment, it is exemplarily assumed that the substrate 1111 is p-type silicon. However, the substrate 1111 is not limited to p-type silicon.

A plurality of doping regions 1311 to 1314 extending along the first direction may be provided over the substrate 1111. For example, the plurality of doping regions 1311 to 1314 may have a second type impurity different from that of the substrate 1111. For example, the plurality of doping regions 1311 to 1314 may be doped with an n-type impurity. In the embodiment, it is exemplarily assumed that the first to fourth doping regions 1311 to 1314 are n-type. However, the first to fourth doping regions 1311 to 1314 are not limited to being n-type.

A plurality of insulation materials 1112 extending along the first direction may be sequentially provided along the second direction over a region of the substrate 1111 between the first and second doping regions 1311 and 1312. For example, the insulation materials 1112 and the substrate 1111 may be spaced apart by a predetermined distance in the second direction. For example, the insulation materials 1112 may be spaced apart from each other in the second direction. For example, the insulation materials 1112 may include an insulator such as silicon oxide.

A plurality of pillars 1113 may be sequentially provided along the first direction over a region of the substrate 111 between the first doping region 1311 and the second doping region 1312, and may be formed to penetrate the insulation materials 1112 along the second direction. For example, each of the plurality of pillars 1113 may penetrate the insulation materials 1112 to contact the substrate 1111. For example, each of the pillars 1113 may be composed of a plurality of materials. For example, a surface layer 1114 of each of the pillars 1113 may include a silicon material having a first type of impurity. For example, the surface layer 1114 of each of the pillars 1113 may include a silicon material doped with the same type impurity as that of the substrate 1111. In this embodiment, it is exemplarily assumed that the surface layer 1114 of each pillar 1113 includes p-type silicon. However, the surface layer 1114 of each pillar 1113 is not limited to p-type silicon.

An inner layer 1115 of each of the pillars 1113 may be formed of an insulation material. For example, the inner layer 1115 of each of the pillars 1113 may be filled with an insulation material such as silicon oxide.

In a region between the first and second doping regions 1311 and 1312, an insulation layer 1116 may be provided along exposed surfaces of the insulation materials 1112, the pillars 1113, and the substrate 1111. For example, the thickness of the insulation layer 1116 may be smaller than half of the distance between the insulation materials 1112. That is, a region, in which a material other than the insulation materials 1112 and the insulation layer 1116 is disposed, may be provided between (i) the insulation layer 1116 provided over the bottom surface of a first insulation material of the insulation materials 1112 and (ii) the insulation layer 1116 provided over the top surface of a second insulation material of the insulation materials 1112. The insulation materials 1112 lie below the first insulation material.

In the region between the first and second doping regions 1311 and 1312, conductive materials 1211 to 1291 may be provided over the surface of the insulation layer 1116. For example, the conductive material 1211 extending along the first direction may be provided between the substrate 1111 and the plural insulation materials 1112, adjacent to the substrate 1111. More specifically, the conductive material 1211 extending along the first direction may be provided between (i) the insulation layer 1116 disposed over the substrate 1111 and (II) the Insulation layer 1116 disposed over the bottom surface of the insulation materials 1112, adjacent to the substrate 1111.

A conductive material extending along the first direction may be provided between (i) the insulation layer 1116 disposed over the top surface of a specific insulation material among the insulation materials 1112 and (ii) the insulation layer 1116 disposed over the bottom surface of another insulation material among the insulation materials 1112, which is disposed over the specific insulation material 1112. For example, a plurality of conductive materials 1221 to 1281 extending along the first direction may be provided between the insulation materials 1112. Also, a conductive material 1291 extending along the first direction may be provided over the uppermost insulation materials 1112. For example, the conductive materials 1211 to 1291 extending along the first direction may be a metallic material. For example, the conductive materials 1211 to 1291 extending along the first direction may be a conductive material such as polysilicon.

The same structure as disposed between the first and second doping regions 1311 and 1312 may be provided between the second and third doping regions 1312 and 1313. For example, the plurality of insulation materials 1112 extending along the first direction, the plurality of pillars 1113 which are sequentially arranged in the first direction and penetrate the plurality of insulation materials 1112 along the second direction, the insulation layer 1116 provided over the surfaces of the plurality of insulation materials 1112 and the plurality of pillars 1113, and the plurality of conductive materials 1212 to 1292 extending along the first direction may be provided between the second and third doping regions 1312 and 1313.

The same structure as disposed between the first and second doping regions 1311 and 1312 may be provided between the third and fourth doping regions 1313 and 1314. For example, the plurality of insulation materials 1112 extending along the first direction, the plurality of pillars 1113 that are sequentially arranged in the first direction and penetrate the plurality of insulation materials 1112 along the second direction, the insulation layer 1116 provided over the surfaces of the plurality of insulation materials 1112 and the plurality of pillars 1113, and the plurality of conductive materials 1213 to 1293 extending along the first direction may be provided between the third and fourth doping regions 1313 and 1314.

Drains 1320 may be provided over the plurality of pillars 1113, respectively. For example, the drains 1320 may be a silicon material doped with a second type material. For example, the drains 1320 may be a silicon material doped with an n-type material. In the embodiment, it is exemplarily assumed that the drains 320 are a silicon material doped with an n-type material. However, the drains 320 will not be limited to n-type silicon materials. For example, the width of the drains 1320 may be wider than that of their corresponding one of the pillars 1113. For example, the drains 1320 may be provided over a top surface of a corresponding one of the pillars 1113 in a pad shape.

Conductive materials 1331 to 1333 extending in the third direction may be provided over the drains 1320. The conductive materials 1331 to 1333 may be sequentially disposed along the first direction. The conductive materials 1331 to 1333 may be respectively coupled to the drains 1320 in the corresponding region. For example, the drains 1320 and the conductive material 1333 extending along the third direction may be coupled to each other through contact plugs, respectively. For example, the conductive materials 1331 to 1333 extending along the third direction may be a metallic material. For example, the conductive materials 1331 to 1333 may be a conductive material such as polysilicon.

Referring to FIGS. 7 and 8, each of the pillars 1113 may be coupled to the insulation layer 1116 and the plurality of conductive materials 1211 to 1291, 1212 to 1292, and 1213 to 1293 extending along the first direction, to form a string. For example, each of the pillars 1113 may form a NAND string NS together with the insulation layer 1116 and the conductive materials 1211 to 1291, 1212 to 1292, and 1213 to 1293 extending along the first direction. The NAND string NS may include a plurality of transistor structures TS.

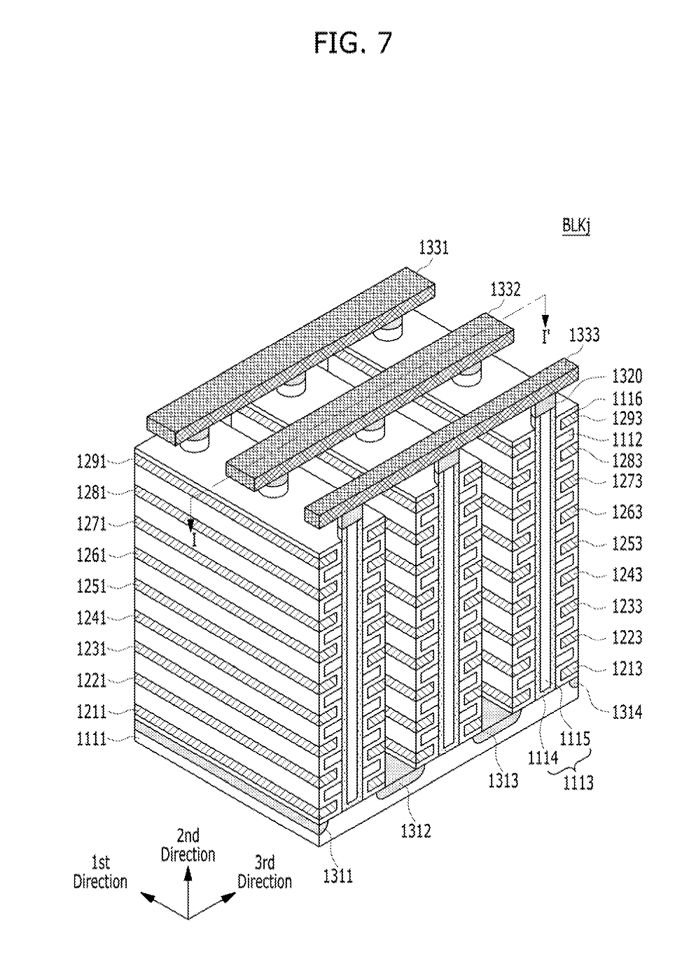

FIG. 9 is a cross-sectional view of the transistor structure TS shown in FIG. 8.

Referring to FIGS. 7 to 9, the insulation layer 1116 may include first to third sub insulation layers 1117, 1118 and 1119.

The surface layer 1114 of P-type silicon in each of the pillars 1113 may serve as a body. The first sub insulation layer 1117, adjacent to each of the pillars 1113, may serve as a tunnelling insulation layer. For example, the first sub insulation layer 1117, adjacent to the each of the pillars 1113, may include a thermal oxide layer.

The second sub insulation layer 1118 may serve as a charge storage layer. For example, the second sub insulation layer 1118 may serve as a charge trap layer. For example, the second sub insulation layer 1118 may include a nitride layer or a metal oxide layer, e.g., aluminium oxide layer, hafnium oxide layer, etc.

The third sub insulation layer 1119 adjacent to a conductive material 1233 may serve as a blocking insulation layer. For example, the third sub insulation layer 1119 adjacent to the conductive material 1233 extending along the first direction may have a mono-layered or multi-layered structure. The third sub insulation layer 1119 may be a high dielectric layer, e.g., aluminium oxide layer, hafnium oxide layer, etc., having a dielectric constant greater than the first and second sub insulation layers 1117 and 1118.

The conductive material 1233 may serve as a gate or control gate. That is, the gate or control gate 1233, the blocking insulation layer 1119, the charge trap layer 1118, the tunnelling insulation layer 1117, and the body 1114 may form a transistor or memory cell transistor structure. For example, the first to third sub insulation layers 1117 to 1119 may form an oxide-nitride-oxide (ONO) structure. In the embodiment, the surface layer 1114 of p-type silicon in each of the pillars 1113 may be referred to as a body in the second direction.

The memory block BLKj may include pillars 1113. That is, the memory block BLKj may include NAND strings NS. More specifically, the memory block BLKj may include NAND strings NS extending along the second direction or a direction perpendicular to the substrate 1111.

Each of the NAND strings NS may include transistor structures TS which are stacked in the second direction. One or more of the plurality of transistor structures TS of each NAND string NS may serve as a string select transistor SST. One or more of the plurality of transistor structures TS of each NAND string may serve as a ground select transistor GST.

The gates or control gates may correspond to the conductive materials 1211 to 1291, 1212 to 1292, and 1213 to 1293 extending along the first direction. That is, the gates or control gates may extend along the first direction to form word lines WL and two or more select lines, e.g., one or more string select line SSL and one or more ground select line GSL.

The conductive materials 1331 to 1333 extending along the third direction may be coupled to one end of the NAND strings NS. For example, the conductive materials 1331 to 1333 extending along the third direction may serve as bit lines BL. That is, in one memory block BLKj, a single bit line BL may be coupled to the plurality of NAND strings.

The second type doping regions 1311 to 1314 extending along the first direction may be coupled to the other end of the NAND strings NS. The second type doping regions 1311 to 1314 extending along the first direction may serve as common source lines CSL.

In summary, the memory block BLKj may include the plurality of NAND strings NS extending along a direction, e.g., a second direction, perpendicular to the substrate 1111, and may operate as a NAND flash memory block, for example, a charge trap type memory, in which the plurality of NAND strings NS is coupled to a single bit line BL.

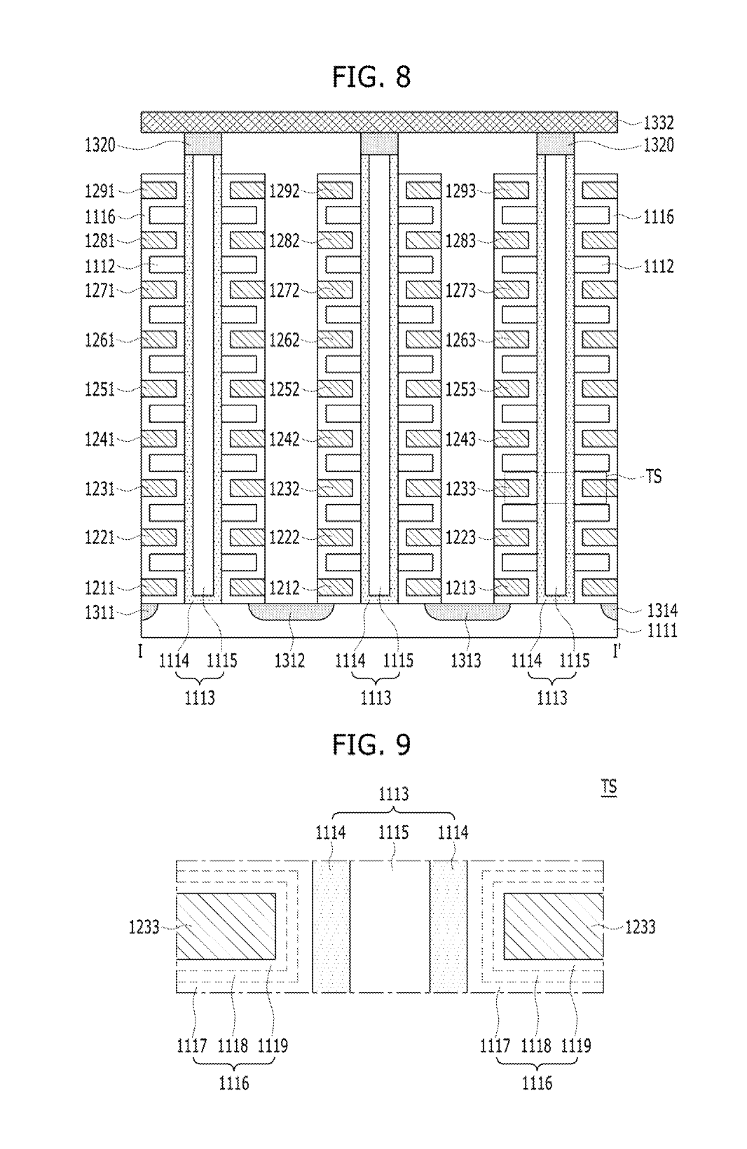

With reference to FIGS. 10 to 12, the conductive materials 1211 to 1291, 1212 to 1292, and 1213 to 1293 extending along the first direction are provided on 9 layers. However, the number of first conductive materials 1211 to 1291, 1212 to 1292, and 1213 to 1293 extending along the first direction is not limited to 9 layers. For example, the conductive materials extending along the first direction may have 8, 16 or more layers. That is, a NAND string may include 8, 16 or more transistors.

With reference to FIGS. 7 to 9, it is described that 3 NAND strings NS are coupled to a single bit line BL. However, the embodiment will not be limited to 3 NAND strings NS coupled to a single bit line BL. In another embodiment, in the memory block BLKj, m NAND strings NS may be coupled to a single bit line BL, m being an integer. Here, the number of the conductive materials 1211 to 1291, 1212 to 1292, and 1213 to 1293 extending along the first direction and the number of common source lines 1311 to 1314 may also be adjusted in response to the number of NAND strings NS coupled to a single bit line BL.

With reference to FIGS. 7 to 9, it is described that 3 NAND strings NS are coupled to a single conductive material extending along the first direction. However, the embodiment will not be limited to 3 NAND strings NS coupled to a single conductive material. In another embodiment, n NAND strings NS may be coupled to a single conductive material, n being an integer. Here, the number of the conductive materials 1331 to 1333 extending along the third direction may also be adjusted in response to the number of NAND strings NS coupled to a single conductive material.

FIG. 10 is an equivalent circuit diagram illustrating the memory block BLKj described with reference to FIGS. 7 to 9.

Referring to FIGS. 7 to 10, NAND strings NS11 to NS31 may be provided between a first bit line BL1 and a common source line CSL. The first bit line BL1 may correspond to the conductive material 1331 extending along the third direction. NAND strings NS12 to NS32 may be provided between a second bit line BL2 and the common source line CSL. The second bit line BL2 may correspond to the conductive material 1332 extending along the third direction. NAND strings NS13 to NS33 may be provided between a third bit line BL3 and the common source line CSL. The third bit line BL3 may correspond to the conductive material 1333 extending along the third direction.

A string select transistor SST of each NAND string NS may be coupled to a corresponding bit line BL. A ground select transistor GST of each NAND string NS may be coupled to the common source line CSL. Memory cells MC may be provided between the string select transistor SST and the ground select transistor GST of each NAND string NS.

The NAND strings NS may be defined in units of rows and columns. The NAND strings NS commonly coupled to a single bit line may form a single column. For example, the NAND strings NS11 to NS31 coupled to the first bit line BL1 may correspond to a first column. The NAND strings NS12 to NS32 coupled to the second bit line BL2 may correspond to a second column. The NAND strings NS13 to NS33 coupled to the third bit line BL3 may correspond to a third column.

The NAND strings NS coupled to a single string select line SSL may form a single row. For example, the NAND strings NS11 to NS13 coupled to a first string select line SSL1 may form a first row. The NAND strings NS21 to NS23 coupled to a second string select line SSL2 may form a second row. The NAND strings NS31 to NS33 coupled to a third string select line SSL3 may form a third row.

A height may be defined for each NAND string NS. For example, the height of the ground select transistor GST may be defined as a value ‘1’ in each NAND string NS. In each NAND string NS, the closer to the string selection transistor SST, the higher the height of the memory cell, when measured from the substrate 1111. In each NAND string NS, the height of the memory cell MC6 adjacent to the string select transistor SST may be defined as a value ‘6’, which is 6 times greater than the ground select transistor GST.

The string select transistors SST of the NAND strings NS of the same row may share the same string select line SSL. The string select transistors SST of the NAND strings NS in different rows may be coupled with different string select lines SSL1, SSL2, and SSL3, respectively.

The memory cells MC having the same height in the NAND strings NS of the same row may share a word line WL. At a predetermined height, the word line WL may be shared by the memory cells MC of the NAND strings NS in different rows, in the same level or the same height. At a predetermined height or at the same level, dummy memory cells DMC of the NAND strings NS of the same row may share a dummy word line DWL. At a predetermined height or level, the dummy memory cells DMC of the NAND strings NS in different rows may share the dummy word lines DWL.

For example, the word lines WL or the dummy word lines DWL located at the same level or height or layer may be commonly coupled on layers where the conductive materials 1211 to 1291, 1212 to 1292, and 1213 to 1293 extending in the first direction are provided. For example, the conductive materials 1211 to 1291, 1212 to 1292, and 1213 to 1293 provided at a given level or height or layer may be coupled to an upper layer via a contact. The conductive materials 1211 to 1291, 1212 to 1292, and 1213 to 1293 extending in the first direction may be coupled in common at the upper layer. The ground select transistors GST of the NAND strings NS of the same row may share the ground select line GSL. The ground select transistors GST of the NAND strings NS in different rows may share the ground select line GSL. That is, the NAND strings NS11 to NS13, NS21 to NS23, and NS31 to NS33 may be coupled in common to the ground select line GSL.

The common source line CSL may be commonly coupled to the NAND strings NS. For example, the first to fourth doping regions 1311 to 1314 may be coupled at an active region of the substrate 1111. For example, the first to fourth doping regions 1311 to 1314 may be coupled to an upper layer via a contact. The first to fourth doping regions 1311 to 1314 may be coupled in common at the upper layer.

As illustrated in FIG. 10, the word lines WL at the same height or level may be commonly coupled. Therefore, when the word line WL at a specific height is selected, all of the NAND strings NS coupled to the selected word line WL may be selected. The NAND strings NS in different rows may be coupled to different string select lines SSL. Accordingly, among the NAND strings NS coupled to the same word line WL, the NAND strings NS of the unselected row may be electrically isolated from the bit lines BL1 to BL3 in response to a selection of the string selection lines SSL1 to SSL3. That is, a row of the NAND strings NS may be selected by selecting one of the string select lines SSL1 to SSL3. The NAND strings NS of the selected row may be selected in units of columns in response to a selection of the bit lines BL1 to BL3.

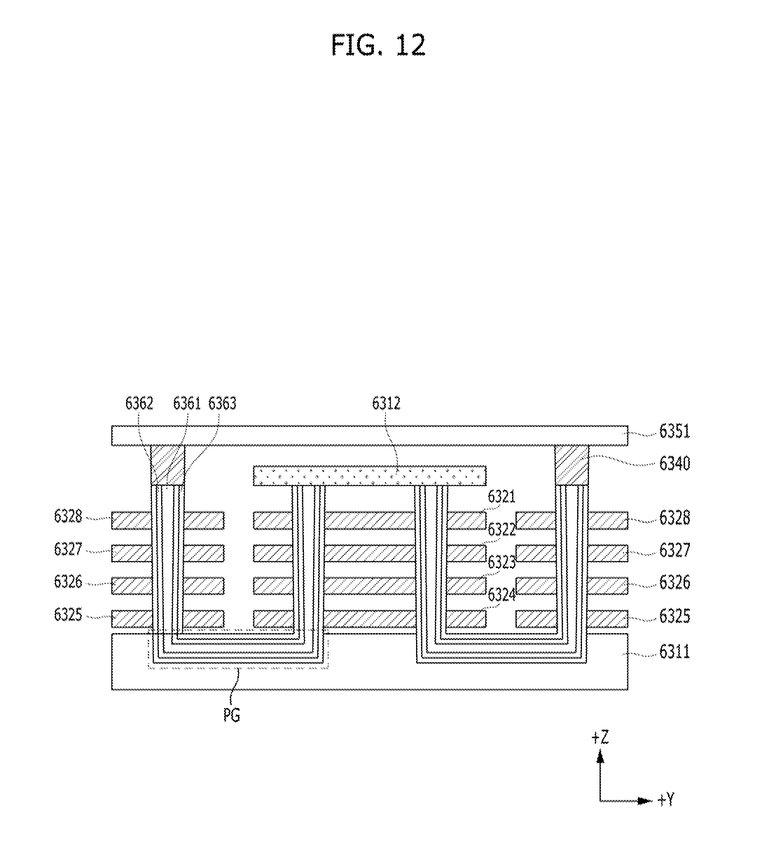

In each NAND string NS, a dummy memory cell DMC may be provided. In FIG. 13, the dummy memory cell DMC is provided between the third memory cell MC3 and the fourth memory cell MC4 in each NAND string NS. That is, the first to third memory cells MC1 to MC3 may be provided between the dummy memory cell DMC and the ground select transistor GST. The fourth to sixth memory cells MC4 to MC6 may be provided between the dummy memory cell DMC and the string select transistor SST. In this embodiment, it is exemplarily assumed that the memory cells MC in each NAND string NS are divided into memory cell groups by the dummy memory cell DMC. A memory cell group, e.g., MC1 to MC3, adjacent to the ground select transistor GST among the memory cell groups may be referred to as a lower memory cell group. A memory cell group, e.g., MC4 to MC6, adjacent to the string select transistor SST among the memory cell groups may be referred to as an upper memory cell group.

An operating method of a semiconductor memory system which includes one or more cell strings each arranged in a direction perpendicular to a substrate coupled with a memory controller and including memory cells, a string select transistor and a ground select transistor, will be described with reference to FIGS. 6 to 10. With the operating method, the semiconductor memory system may be provided with a first read command to perform first and second hard decision read operations in response to a first hard decision read voltage and a second hard decision read voltage that is different from the first hard decision read voltage, may acquire hard decision data, may select one of the first and second hard decision voltages based on an error bit state of the hard decision data, may acquire soft decision data in response to a soft read voltage that is different from the first and second hard decision read voltages, and provide the soft decision data to a memory controller.

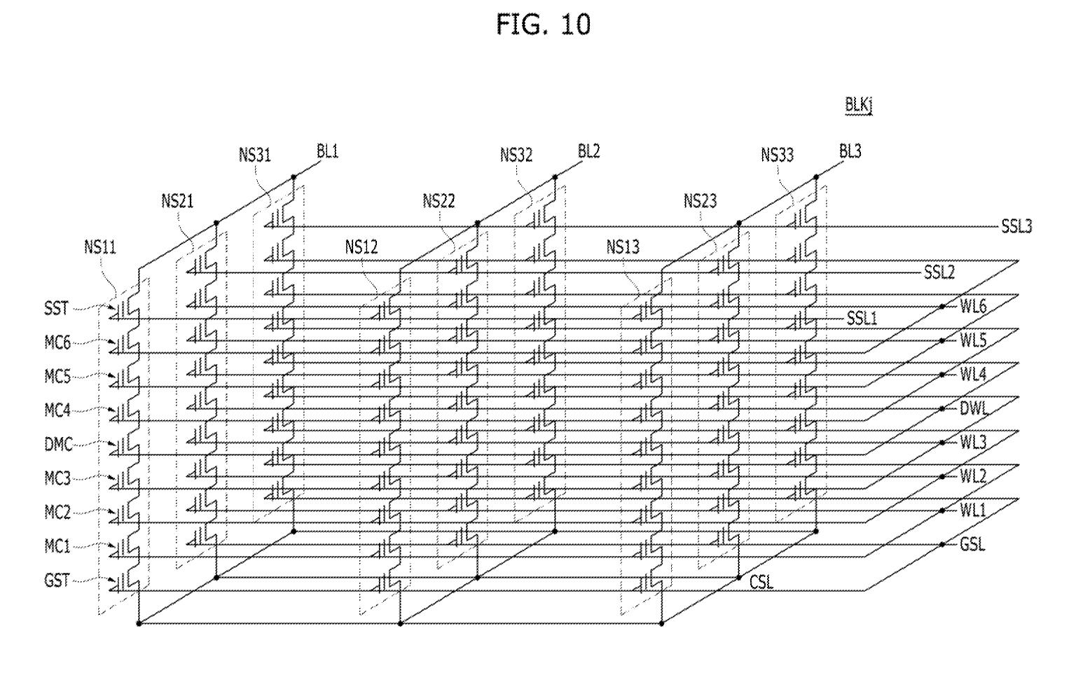

FIGS. 11 to 13 are diagrams schematically illustrating a 3D nonvolatile memory device in accordance with an embodiment of the present invention. FIGS. 11 to 13 illustrate the semiconductor memory system, for example, a flash memory device implemented in 3D in accordance with an embodiment of the present invention.

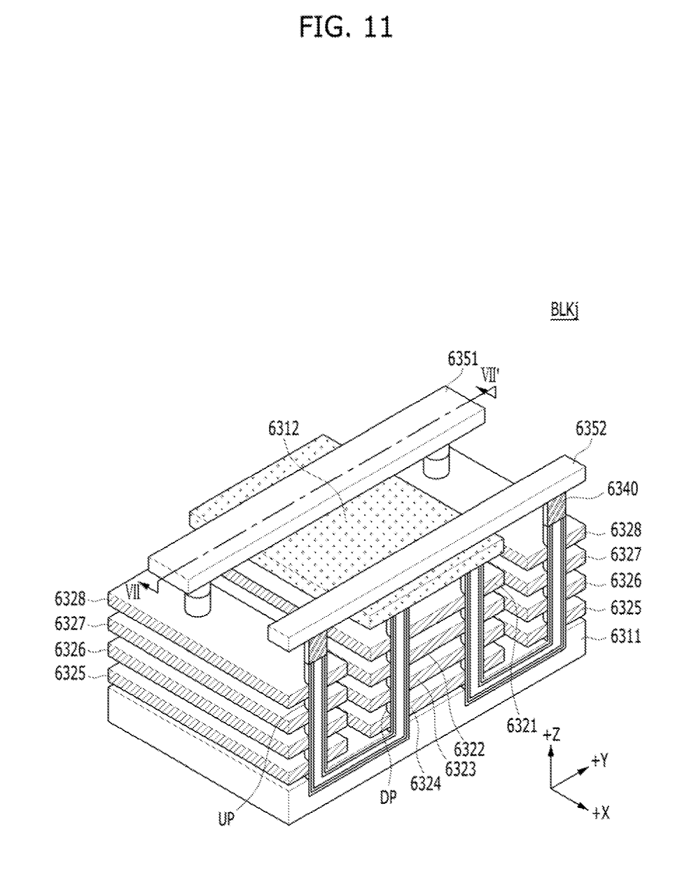

FIG. 11 is a perspective view illustrating one memory block BLKj of the memory blocks 210 shown in FIG. 6. FIG. 12 is a sectional view illustrating the memory block BLKj taken along the line VII-VII′ shown in FIG. 11.

Referring to FIGS. 11 and 12, the memory block BLKj may include a structure extending along first to third directions.

A substrate 6311 may be provided. For example, the substrate 6311 may include a silicon material doped by a first type impurity. For example, the substrate 6311 may include a silicon material doped by a p-type impurity or a p-type well, e.g., a pocket p-well. The substrate 6311 may further include an n-type well surrounding the p-type well. In the embodiment, it is exemplarily assumed that the substrate 6311 is p-type silicon. However, the substrate 6311 will not be limited to p-type silicon.

First to fourth conductive material layers 6321 to 6324 extending along the X-direction and the Y-direction may be disposed over the substrate 6311. The first to fourth conductive material layers 6321 to 6324 may be spaced apart from one another in the Z-direction.

Fifth to eighth conductive material layers 6325 to 6328 extending along the X-direction and the Y-direction may be disposed over the substrate 6311. The fifth to eighth conductive material layers 6325 to 6328 may be spaced apart from one another in the Z-direction. The fifth to eighth conductive material layers 6325 to 6328 may be spaced apart from the first to fourth conductive material layers 6321 to 6324 in the Y-direction.

A plurality of lower pillars DP may be formed to penetrate the first to fourth conductive material layers 6321 to 6324. Each of the lower pillars DP may be extended in the Z-direction. A plurality of upper pillars UP may be formed to penetrate the fifth to eighth conductive material layers 6325 to 6328. Each of the upper pillars UP may be extended in the Z-direction.

Each of the lower pillars DP and the upper pillars UP may include an internal material layer 6361, a middle layer 6362 and a surface layer 6363. The middle layer 6362 may serve as a channel of the cell transistor. The surface layer 6363 may include a blocking insulating layer, an electric charge storage layer and a tunnel insulating layer.

The lower pillars DP and the upper pillars UP may be coupled through a pipe gate PG. The pipe gate PG may be formed in the substrate 6311. For example, the pipe gate PG may include substantially the same material as the plural lower pillars DP and the plural upper pillars UP.

A doping material layer 6312 with a second impurity type may be disposed on the plural lower pillars DP. The doping material layer 6312 may extend in the X direction and the Y direction. For example, the doping material layer 6312 with the second impurity type may include n-type silicon material. The doping material layer 6312 with the second impurity type may serve as the common source line CSL.

Drains 6340 may be formed on each of the plural upper pillars UP. For example, the drain 6340 may include n-type silicon material, first and second upper conductive material layers 6351 and 6352 may be formed on the drains 6340. The first and second upper conductive material layers 6351 and 6352 may be extended in the Y-direction.

The first and second upper conductive material layers 6351 and 6352 may be spaced apart from each other in the X-direction. For example, the first and second upper conductive material layers 6351 and 6352 may be made up of metal. For example, the first and second upper conductive material layers 6351 and 6352 may be coupled to drains 6340 through contact plugs. The first and second upper conductive material layers 6351 and 6352 may serve as first and second bit lines BL1 and BL2, respectively.

The first conductive material layer 6321 may serve as the source select line SSL, and the second conductive material layer 6322 may serve as the first dummy word line DWL1, and the 3rd and 4th conductive material layers 6323 and 6324 may serve as the first and second main word lines MWL1 and MWL2, respectively. The 5th and 6th conductive material layers 6325 and 6326 may serve respectively as the 3rd and 4th main word lines MWL3 and MWL4, the 7th conductive material layer 6327 may serve as the second dummy word line DWL2, and the 8th conductive material layer 6328 may serve as the drain select line DSL.

Each of the plural lower pillars DP and the first to 4th conductive material layers 6321 to 6324 adjacent to the lower pillar DP may form a lower string. Each of the plural upper pillars UP and the 5th to 8th conductive material layers 6325 to 6328 adjacent to the upper pillar UP may form an upper string. The lower string and the upper string may be coupled through the pipe gate PG. One end of the lower string may be coupled to the second-type doping material layer 6312 serving as the common source line CSL. One end of the upper string may be coupled to a corresponding bit line through the drain 6320. The lower string and the upper string are coupled through the pipe gate PG. A single lower string and a single upper string may form a single cell string coupled between the second-type doping material layer 6312 and corresponding bit line.

That is, the lower string may include the source select transistor SST, the first dummy memory cell DMC1, and the first and second main memory cells MMC1 and MMC2. The upper string may include the 3rd and 4th main memory cells MMC3 and MMC4, the second dummy memory cell DMC2 and the drain select transistor DST.

Referring to FIGS. 11 and 12, the upper string and the lower string may form the NAND string NS having a plurality of transistor structures TS. The structure of the transistor TS may be the same as described with reference to FIG. 9.

FIG. 13 is an equivalent circuit diagram illustrating the memory block BLKj described with reference to FIGS. 11 and 12. FIG. 13 exemplarily shows first and second strings among the strings included in the memory block BLKj.

Referring to FIG. 13, the memory block BLKj may include a plurality of cell strings, each of which comprises a single upper string and a single lower string coupled to each other through the pipe gate PG, as described with reference to FIGS. 11 and 12.

In the memory block BLKj, memory cells stacked along a first channel layer CH1, one or more source selection gates, and one or more drain selection gates may form a first string ST1. Memory cells stacked along a second channel layer CH2, one or more source selection gates, and one or more drain selection gates may form a second string ST2.

The first and second strings ST1 and ST2 may be coupled to a single drain selection line DSL and a single source selection line SSL. The first string ST1 may be coupled to a first bit line BL1, and the second string ST2 may be coupled to a second bit line BL2.

FIG. 13 shows the first and second strings ST1 and ST2 coupled to a single drain selection line DSL and a single source selection line SSL the first and second strings ST1 and ST2 may be coupled to a single source selection line SSL and a single bit line BL. In such case, the first string ST1 may be coupled to the first drain selection line DSL1, and the second string ST2 may be coupled to the second drain selection line DSL2. In another embodiment, the first and second strings ST1 and ST2 may be coupled to a single drain selection line DSL and a single bit line BL. In such case, the first string ST1 may be coupled to the first source selection line SSL1, and the second string ST2 may be coupled to the second source selection line SSL2.

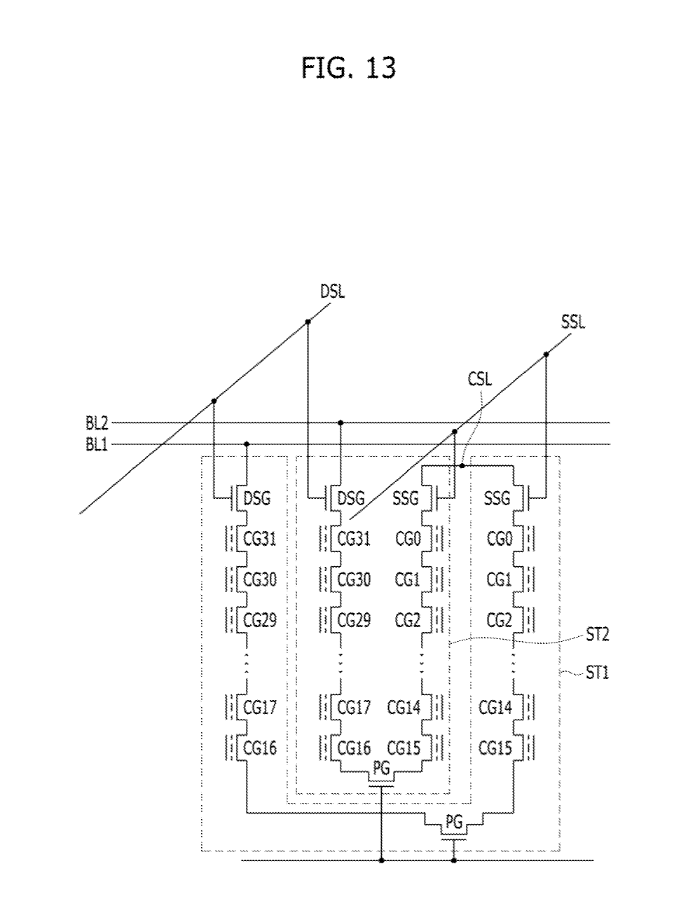

FIG. 14 is a block diagram schematically illustrating an electronic device 10000 including a memory controller 15000 and a flash memory 16000 in accordance with an embodiment of the present invention.

Referring to FIG. 14, the electronic device 10000, which could be a cellular phone, a smart phone, or a tablet PC may include the flash memory 16000 implemented by a flash memory device and the memory controller 15000 to control the flash memory 16000.

The flash memory 16000 may correspond to the semiconductor memory system 110 described above with reference to FIGS. 3 to 13. The flash memory 16000 may store random data.

The memory controller 15000 may be controlled by a processor 11000 which controls overall operations of the electronic device 10000.

Data stored in the flash memory 16000 may be displayed through a display 13000 under the control of the memory controller 15000. The memory controller 15000 operates under the control of the processor 11000.

A radio transceiver 12000 may receive and output a radio signal through an antenna ANT. For example, the radio transceiver 12000 may convert the received radio signal from the antenna ANT into a signal to be processed by the processor 11000. Thus, the processor 11000 may process the converted signal from the radio transceiver 12000, and may store the processed signal at the flash memory 16000. Otherwise, the processor 11000 may display the processed signal through the display 13000.

The radio transceiver 12000 may convert a signal from the processor 11000 into a radio signal, and may output the converted radio signal externally through the antenna ANT.

An input device 14000 may receive a control signal for controlling an operation of the processor 11000 or data to be processed by the processor 11000, and may be implemented by a pointing device such as a touch pad or a computer mouse, a key pad, or a keyboard.

The processor 11000 may control the display 13000 such that data from the flash memory 16000, the radio signal from the radio transceiver 12000, or the data from the input device 14000 is displayed through the display 13000.

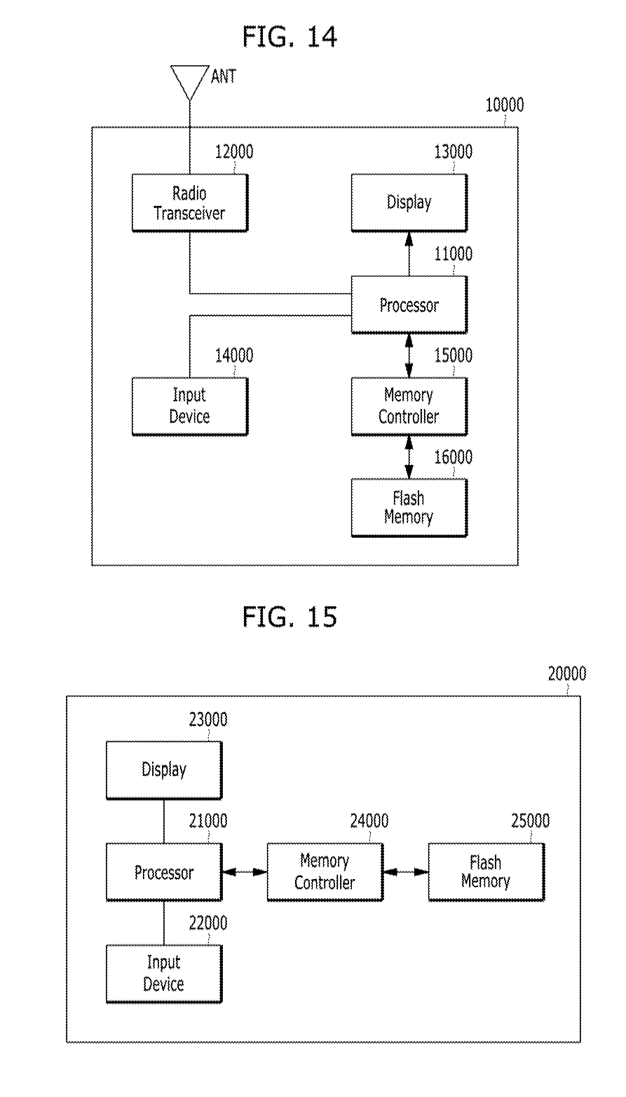

FIG. 15 is a block diagram schematically illustrating an electronic device 20000 including a memory controller 24000 and a flash memory 25000 in accordance with an embodiment of the present invention.

Referring to FIG. 15, the electronic device 20000 may be implemented by a data processing device such as a personal computer (PC), a tablet computer, a net-book, an e-reader, a personal digital assistant (PDA), a portable multimedia player (PMP), an MP3 player, or an MP4 player, and may include the flash memory 25000, e.g., the flash memory device, and the memory controller 24000 to control an operation of the flash memory 25000.

The electronic device 20000 may include a processor 21000 to control overall operations of the electronic device 20000. The memory controller 24000 may be controlled by the processor 21000.

The processor 21000 may display data stored in the semiconductor memory system through a display 23000 in response to an input signal from an input device 22000. For example, the input device 22000 may be implemented by a pointing device such as a touch pad or a computer mouse, a key pad, or a keyboard.

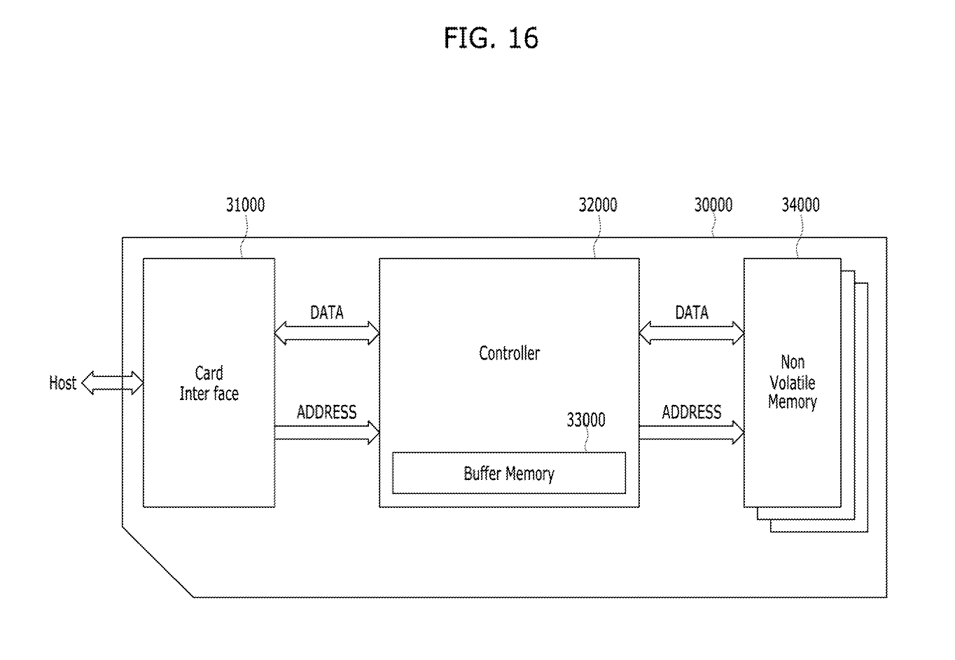

FIG. 16 is a block diagram schematically illustrating an electronic device 30000 including a controller 32000 and a semiconductor memory system 34000 in accordance with an embodiment of the present invention.

Referring to FIG. 16, the electronic device 30000 may include a card interface 31000, the controller 32000, and the semiconductor memory system 34000, for example, a flash memory device.

The electronic device 30000 may exchange data with a host through the card interface 31000. The card interface 31000 may be a secure digital (SD) card interface or a multi-media card (MMC) interface, which does not limit the scope of the present invention. The card interface 31000 may interface the host and the controller 32000 according to a communication protocol of the host that is capable of communicating with the electronic device 30000.

The controller 32000 may control overall operations of the electronic device 30000, and may control data exchange between the card interface 31000 and the semiconductor memory system 34000. A buffer memory 33000 of the controller 32000 may buffer data transferred between the card interface 31000 and the semiconductor memory system 34000.

The controller 32000 may be coupled with the card interface 31000 and the semiconductor memory system 34000 through a data bus DATA and an address bus ADDRESS. In accordance with an embodiment, the controller 32000 may receive an address of data, which is to be read or written, from the card Interface 31000 through the address bus ADDRESS, and may send it to the semiconductor memory system 34000. Further, the controller 32000 may receive or transfer data to be read or written through the data bus DATA connected with the card interface 31000 or the semiconductor memory system 34000.

When the electronic device 30000 is connected with the host such as a PC, a tablet PC, a digital camera, a digital audio player, a mobile phone, console video game hardware or a digital set-top box, the host may exchange data with the semiconductor memory system 34000 through the card interface 31000 and the controller 32000.

While the present invention has been described with respect to the specific embodiments, it will be apparent to those skilled in the art that various changes and modifications may be made without departing from the spirit and scope of the invention as defined in the following claims.

What is claimed is:

1. A method of operating a semiconductor memory system, the method comprising:
programming LSB data into a memory cell of a selected word line included in a memory block;
receiving MSB data to be programmed into the memory cell of the selected word line, from a controller into a page buffer;
reading the programmed LSB data from the memory cell of the selected word line;
performing an error correction code (ECC) operation on the read LSB data when a difference between a reference amount and an amount of bit line current, which flows through bit lines included in the memory block, does not fall in a predetermined range from a first current amount to a second current amount; and
programming the MSB data stored in the page buffer into the memory cell of the selected word line based on the ECC-corrected LSB data.

2. The method of claim 1, wherein a read voltage is applied to the selected word line included in the memory block for the reading of the programmed LSB data.

3. The method of claim 1, wherein the amount of bit line current is an amount of current flowing through the bit lines included in the memory block during the reading of the programmed LSB data.

4. The method of claim 1, wherein the reference amount is a total amount of current flowing through turned-on and turned-off bit lines included in the memory block.

5. The method of claim 1,
wherein the first current amount is determined when the number of turned-off memory cells of the selected word line becomes approximately 49% of the total number of memory cells in a single word line, and
wherein the second current amount is determined when the number of turned-off memory cells of the selected word line becomes approximately 51% of the total number of memory cells in a single word line.

6. The method of claim 1, further comprising:
programming the MSB data stored in the page buffer into the memory cell of the selected word line based on the read LSB data when the difference between the reference amount and the amount of bit line current falls in the predetermined range from the first current amount to the second current amount.

7. The method of claim 1, wherein the ECC-corrected LSB data are provided from the controller.

8. The method of claim 7, wherein the controller corrects an error included in the read LSB data through a signal process.

9. A method of operating a semiconductor memory system, the method comprising:
programming LSB data into a memory cell of a selected word line included in a memory block;
receiving MSB data to be programmed into the memory cell of the selected word line, from a controller into a page buffer;
reading the programmed LSB data from the memory cell of the selected word line in response to a read voltage;
when a difference between a reference amount and an amount of bit line current, which flows through bit lines included in the memory block, does not fall in a predetermined range from a first current amount to a second current amount, reading the programmed LSB data from the memory cell of the selected word line by changing the read voltage until the difference falls in the predetermined range; and
programming the MSB data stored in the page buffer into the memory cell of the selected word line based on the read LSB data when the difference falls in the predetermined range.

10. The method of claim 9, wherein the amount of bit line current is an amount of current flowing through the bit lines included in the memory block during the reading of the programmed LSB data.

11. The method of claim 9, the reference amount is a total amount of current flowing through turned-on and turned-off bit lines included in the memory block.

12. The method of claim 9,
wherein the first current amount is determined when the number of turned-off memory cells of the selected word line becomes approximately 49% of the total number of memory cells of a single word line, and
wherein the second current amount is determined when the number of turned-off memory cells of the selected word line becomes approximately 51% of the total number of memory cells of a single word line.

13. The method of claim 9, further comprising:
programming the MSB data stored in the page buffer into the memory cell of the selected word line based on the read LSB data when the difference between the reference amount and the amount of bit line current falls in the predetermined range from the first current amount to the second current amount.

14. A semiconductor memory system comprising:
a page buffer including LSB data and MSB data;
a memory block including a memory cell suitable for storing the LSB data and the MSB data provided from the page buffer; and
a current management unit suitable for determining whether a difference between a reference amount and an amount of bit line current, which flows through bit lines included in the memory block when the LSB data programmed in the memory cell are read for the MSB data to be programmed into the memory cell, falls in a predetermined range from a first current amount to a second current amount,
wherein the semiconductor memory system performs an error correction code (ECC) operation on the LSB data when the difference between the reference amount and the amount of bit line current does not fall in the predetermined range, and the page buffer programs the MSB data based on the ECC-corrected LSB data.

15. The semiconductor memory system of claim 14, wherein the amount of bit line current is an amount of current flowing through the bit lines included in the memory block when the LSB data programmed in the memory cell are read for the MSB data to be programmed into the memory cell.

16. The semiconductor memory system of claim 14, wherein the reference amount is a total amount of current flowing through turned-on and turned-off bit lines included in the memory block.

17. The semiconductor memory system of claim 14,
wherein the first current amount is determined when the number of turned-off memory cells of a selected word line becomes approximately 49% of the total number of memory cells in a single word line, and
wherein the second current amount is determined when the number of turned-off memory cells of the selected word line becomes approximately 51% of the total number of memory cells in a single word line.

18. A semiconductor memory system comprising:
a memory block including a memory cell in which LSB data are programmed;
a voltage supply unit suitable for supplying a read voltage for reading the LSB data programmed in the memory cell;
a page buffer suitable for receiving MSB data from a controller, and reading the LSB data programmed in the memory cell; and
a current management unit suitable for determining whether a difference between a reference amount and an amount of bit line current, which flows through bit lines included in the memory block when the LSB data programmed in the memory cell are read for the MSB data to be programmed into the memory cell, falls in a predetermined range from a first current amount to a second current amount,
wherein when the difference does not fall in the predetermined range, the voltage supply unit changes the read voltage until the difference falls in the predetermined range, and the page buffer reads the LSB data programmed in the memory cell in response to the changed read voltage.

19. The semiconductor memory system of claim 18, wherein the amount of bit line current is an amount of current flowing through the bit lines included in the memory block when the LSB data programmed in the memory cell are read for the MSB data to be programmed into the memory cell.

20. The semiconductor memory system of claim 18, wherein the reference amount is a total amount of current flowing through turned-on and turned-off bit lines included in the memory block.

21. The semiconductor memory system of claim 18,
wherein the first current amount is determined when the number of turned-off memory cells of a selected word line becomes approximately 49% of the total number of memory cells in a single word line, and
wherein the second current amount is determined when the number of turned-off memory cells of the selected word line becomes approximately 51% of the total number of memory cells in a single word line.
